(19) United States
(12) Patent Application Publication
(10) Pub. No.: US 2024/0072157 A1
(43) Pub. Date: Feb. 29, 2024

(54) SEMICONDUCTOR STRUCTURE AND FORMING METHOD THEREOF

(71) Applicant: TAIWAN SEMICONDUCTOR MANUFACTURING COMPANY LTD., HSINCHU (TW)

(72) Inventor: CHANSYUN DAVID YANG, HSINCHU (TW)

(21) Appl. No.: 17/822,123

(22) Filed: Aug. 24, 2022

(51) Int. Cl. H01L 29/66; H01L 29/775; H01L 29/06; H01L 21/8234; H01L 29/786

(52) U.S. Cl. CPC H01L 29/6656; H01L 29/775; H01L 29/0673; H01L 29/66439; H01L 21/823412; H01L 21/823468; H01L 29/78696

(57) ABSTRACT

A method for forming a semiconductor structure is provided. A structure including a sacrificial spacer interposed between a metal gate structure and a dielectric structure is received. A temperature of the sacrificial spacer is increased. At least a portion of the sacrificial spacer is removed to form a recess between the metal gate structure and the dielectric structure. A spacer is formed in the recess along a sidewall of the metal gate structure. A semiconductor structure is also provided.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a flowchart representing a method for forming a semiconductor structure according to aspects of one or more embodiments of the present disclosure.

FIG. 2 is a flowchart representing a method for forming a semiconductor structure according to aspects of one or more embodiments of the present disclosure.

FIG. 3 is a cross-sectional view illustrating a processing system according to aspects of the present disclosure in one or more embodiments.

FIG. 4 is a schematic drawing illustrating a semiconductor structure at a fabrication stage constructed according to aspects of the present disclosure in one or more embodiments.

FIGS. 5 to 13 are schematic drawings illustrating the semiconductor structure at various fabrication stages constructed according to aspects of the present disclosure in one or more embodiments.

FIGS. 14 to 18 are schematic drawings illustrating a semiconductor structure at various fabrication stages constructed according to aspects of the present disclosure in one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. The specific embodiments discussed are merely illustrative of specific ways to make and use the embodiments, and do not limit the scope of the disclosure. Throughout the various views and illustrative embodiments, like reference numerals are used to designate like elements. Reference will now be made in detail to exemplary embodiments illustrated in the accompanying drawings. Wherever possible, same reference numbers are used in the drawings and the description to refer to same or similar parts. In the drawings, shape and thickness may be exaggerated for clarity and convenience. It should be appreciated that the following figures are not drawn to scale; rather, these figures are merely intended for illustration.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Multi-gate transistors including fin field-effect transistors (FinFET) and gate-all-around (GAA) transistors have been introduced in an effort to improve gate control. Replacing polysilicon gates with high-k metal gate (HKMG) structures has brought about improvement in device performance as feature sizes continue to decrease. By combining the metal gate electrode and the high-k gate insulator layer in the multi-gate transistors, HKMG technology makes further scaling possible. However, as the dimensions of transistors decrease, various issues may arise. For example, a spacer structure may be damaged during or after formation of the HKMG structures. For another example, use of high-k dielectric materials may generally increase parasitic capacitance. In many instances, such increase in parasitic capacitance may lead to compromised device performance because it generally increases the RC delay of devices. Accordingly, an alternative approach to forming the multi-gate transistor device with reduced parasitic capacitance or greater speed is therefore of primary importance.

Some embodiments of the present disclosure provide a semiconductor structure and methods for manufacturing a semiconductor structure that provide one or more improvements over existing approaches. By using an in-situ selective heating assisted plasma etching operation as introduced below, an etch selectivity between a target dielectric material and adjacent dielectric materials may be increased. Accordingly, a removal of the target dielectric material may be achieved without substantially etching and/or damaging nearby dielectric materials. Following the removal of the target dielectric material, a removal of a gate dielectric may be achieved without substantially etching and/or damaging nearby structures. Furthermore, with the removal of the gate dielectric, the resulting transistor device may have a reduced parasitic capacitance or greater speed. Additionally, since the selective heating operation may be performed in-situ in a same chamber as the plasma etching operation, the proposed method may provide benefits by lowering associated costs and/or increasing production efficiency.

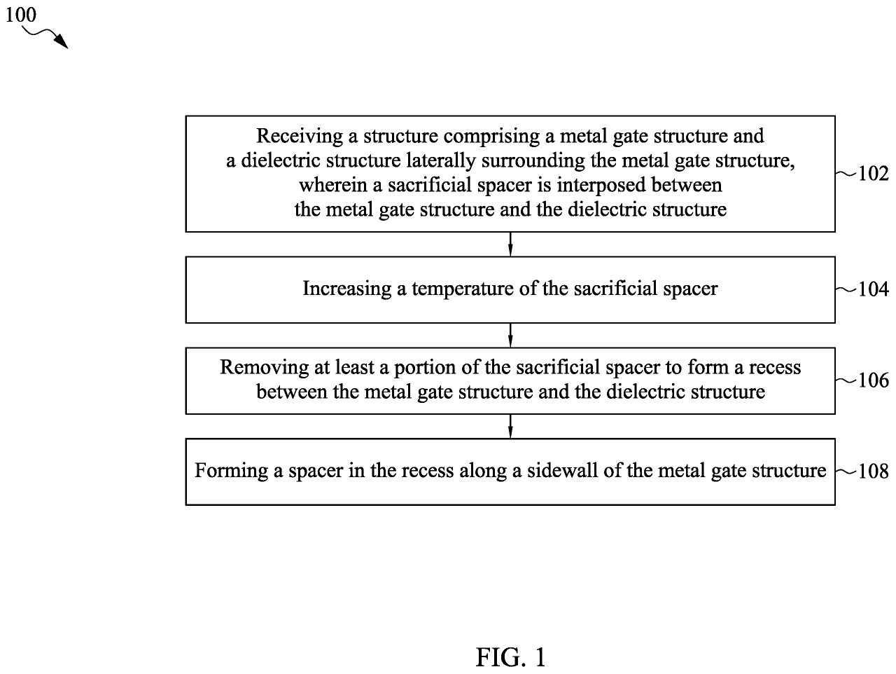

FIG. 1 is a flowchart representing a method 100 for forming a semiconductor structure according to aspects of one or more embodiments of the present disclosure. The method 100 includes an operation 102, in which a structure is received. In some embodiments, the structure includes a metal gate structure and a dielectric structure laterally surrounding the metal gate structure, wherein a sacrificial spacer is interposed between the metal gate structure and the dielectric structure. The method 100 includes an operation 104, in which a temperature of the sacrificial spacer is increased. The method 100 includes an operation 106, in which at least a portion of the sacrificial spacer is removed to form a recess between the metal gate structure and the dielectric structure. The method 100 includes an operation 108, in which a spacer is formed in the recess along a sidewall of the metal gate structure. The method 100 for forming the semiconductor structure will be further described according to one or more embodiments. It should be noted that the operations of the method 100 may be rearranged or otherwise modified within the scope of the various aspects. It should be further noted that additional operations may be provided before, during, and after the method 100, and that some other operations may only be briefly described herein. Thus, other implementations are possible within the scope of the various aspects described herein.

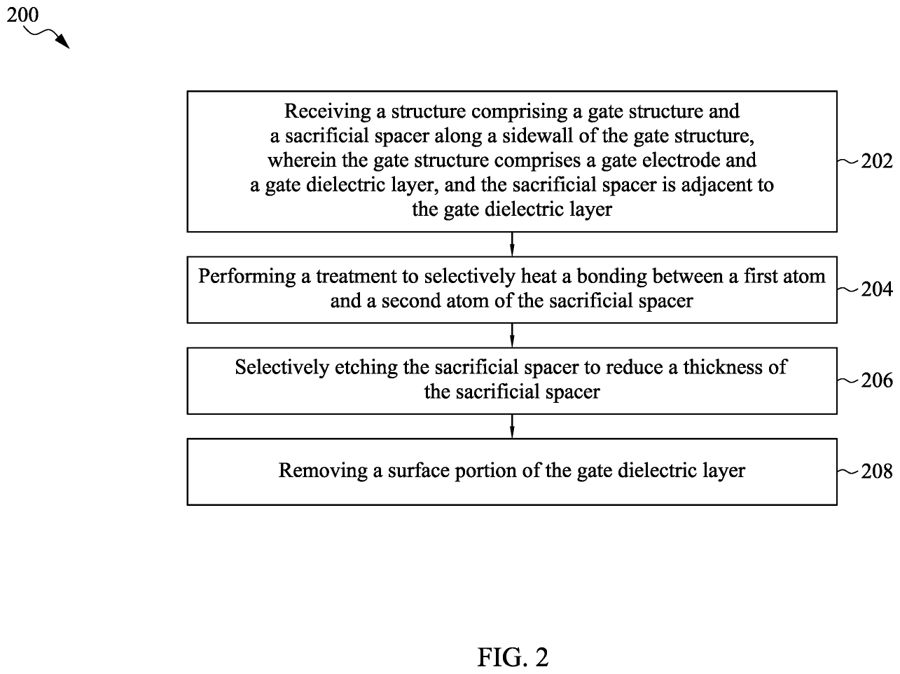

FIG. 2 is a flowchart representing a method 200 for forming a semiconductor structure according to aspects of one or more embodiments of the present disclosure. The method 200 includes an operation 202, in which a structure is received. In some embodiments, the structure includes a gate structure and a sacrificial spacer along a sidewall of the gate structure, wherein the gate structure comprises a gate electrode and a gate dielectric layer, and the sacrificial spacer is adjacent to the gate dielectric layer. The method 200 includes an operation 204, in which a treatment is preformed to selectively heat a bonding between a first atom and a second atom of the sacrificial spacer. The method 200 includes an operation 206, in which the sacrificial spacer is selectively etched to reduce a thickness of the sacrificial spacer. The method 200 includes an operation 208, in which a surface portion of the gate dielectric layer is removed. The method 200 for forming the semiconductor structure will be further described according to one or more embodiments. It should be noted that the operations of the method 200 may be rearranged or otherwise modified within the scope of the various aspects. It should be further noted that additional operations may be provided before, during, and after the method 200, and that some other operations may only be briefly described herein. Thus, other implementations are possible within the scope of the various aspects described herein.

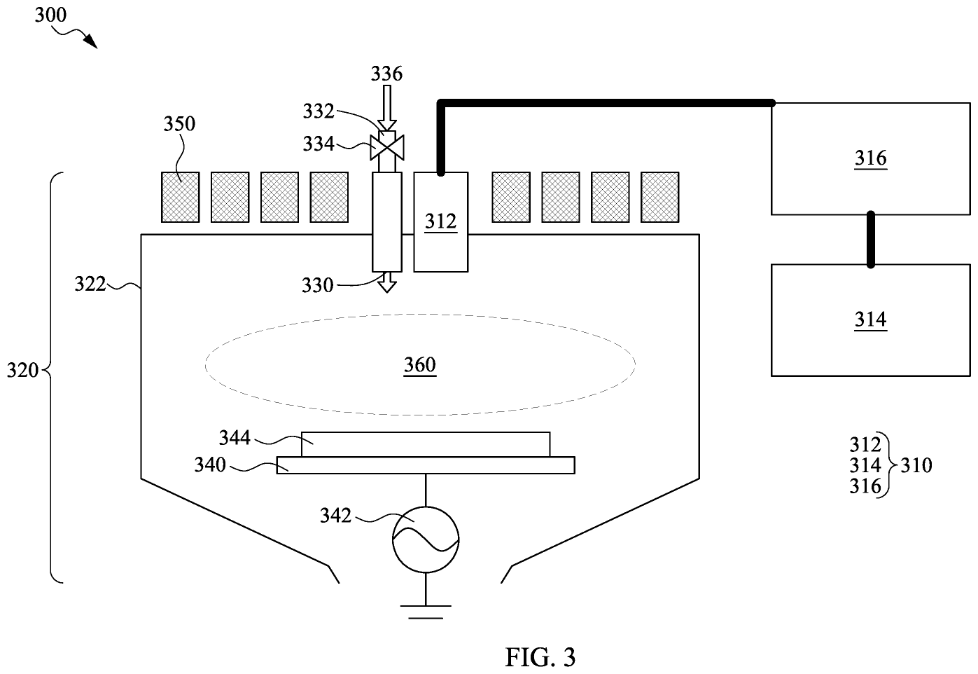

FIG. 3 is a cross-sectional view illustrating a processing system 300 according to aspects of the present disclosure in one or more embodiments. The processing system 300 may be utilized for etching operations, and more particularly to in-situ selective heating assisted etching operations. The processing system 300 may include an antenna system 310 and a plasma etching system 320. The antenna system 310 may be a millimeter wave beamforming antenna system or a microwave wave beamforming antenna system. The antenna system 310 may include a beamforming antenna 312, a control unit 314 and a generator 316. The beamforming antenna 312 may be a millimeter wave beamforming antenna or a microwave wave beamforming antenna. The control unit 314 may include a microwave/millimeter wave power controller and/or a microwave/millimeter wave circuit controller. The generator 316 connected to the beamforming antenna 312 may generate a millimeter wave or a microwave wave at a selected frequency. The beamforming antenna 312 may direct the millimeter wave or the microwave wave with the selected frequency to the chamber 322.

The plasma etching system 320 may be a transformer coupled plasma (TCP) etching system, an inductively coupled plasma (ICP) etching system or a capacitively coupled plasma (CCP) etching system. The plasma etching system 320 may include a chamber 322, a shower head 330 and a wafer holder 340 in the chamber 322, a gas line 332 connected to the chamber 322, and a radio frequency (RF) generator 342 connected to the wafer holder 340. The shower head 330 may connect to the gas line 332 and release gases 336 from the gas line 332 into the chamber 322. The gas line 332 may include a valve 334 controlling a gas flow of the gas 336. In some embodiments, the gas 336 may be delivered from a gas cabinet (not shown). In some embodiments, the gas 336 may be a plasma of etching gases generated by a remote plasma generator (not shown). The gas line 332 may direct the plasma of the etching gases to the shower head 330 in the chamber 322. The wafer holder 340 may be an electrostatic wafer chuck and may be configured to hold a wafer 344. In some embodiments, the RF generator 342 may connect to the wafer holder 340, and may apply a bias RF signal to the wafer holder 340. The plasma etching system 320 may further include a coil 350, such as a TCP coil, disposed over the chamber 322. In some embodiments, the coil 350 is placed and arranged over a dielectric window (not shown) of the chamber 322. A plasma region 360 may be formed in the chamber 322. The plasma region 360 may include ions or radicals used to etch features, surfaces and materials of the wafer 344.

The antenna system 310 may be arranged over and attached to the chamber 322 of the plasma etching system 320 for in-situ selective heating assisted plasma etching operations. The plasma etching operation may be performed by applying electromagnetic energy (e.g., radio frequency) to a gas (e.g., gas 336) that contains a chemically reactive element to form a plasma. The plasma releases charged ions that can bombard the surface of the wafer 344 to remove or etch the target material, such as a low-k dielectric layer. In some embodiments, the low-k dielectric layer is laterally surrounded by a high-k dielectric layer and/or a hard mask layer. As used herein, the term “low-k” refers to a low dielectric constant, and the term “high-k” refers to a high dielectric constant. In the field of semiconductor device structures and manufacturing processes, low-k refers to a dielectric constant that is less than the dielectric constant of SiO₂ (e.g., less than about 3.9), while high-k refers to a dielectric constant that is greater than the dielectric constant of SiO₂ (e.g., greater than 3.9). When multiple layers (i.e., the low-k dielectric layer, the high-k dielectric layer and the hard mask layer) are on the surface of the wafer 344, for example during the removal of the low-k dielectric layer, the etch operation is required to remove the low-k dielectric layer but preserve other layers (e.g., the high-k dielectric layer, the hard mask layer, etc.), and the selectivity of the etch operation becomes an important parameter. Selectivity of an etch chemistry or an etch operation may be defined as the ratio of two etch rates: the ratio of the rate of the layer to be removed to the rate of the layer to be preserved. In an etch operation, high selectivity ratios (e.g., greater than 10:1) are desirable. The term “etch selectivity” may refer to the ratio of the etch rates of two different materials under same etching conditions. Higher etch selectivity may be an objective in an etch operation.

Various embodiments of the present disclosure provide in-situ selective heating assisted plasma etching operations through the processing system 300. In some embodiments, the in-situ selective heating assisted plasma etching operations may increase an etch selectivity between the low-k dielectric material and adjacent dielectric materials (e.g., the high-k dielectric material and/or the hard mask material) on the wafer 344. The in-situ selective heating assisted plasma etching operations may increase the etch selectivity between the low-k dielectric material and adjacent materials by selectively heating the target material through a wave (e.g., an electromagnetic wave, such as RF, microwave, millimeter wave, or IR) provided by the antenna system 310. The wave may heat and/or cool the target material within a few milliseconds through switching on and switching off of millimeter-wave radiation. Different dielectric materials may be heated at different specific frequencies (e.g., loss tangent EM wave). The specific frequency depends on the thickness, composition, grain size, film quality, film density, porosity, dielectric constant (ε′), dielectric loss factor (ε″), and other material properties. The wave having a selected frequency may selectively heat the target material and increase a temperature of the target material, while temperatures of adjacent dielectric materials remain unchanged. Accordingly, the etch selectivity between the low-k dielectric material and adjacent dielectric materials may be increased. Furthermore, the in-situ selective heating may be applied to different target materials such as SiC, SiON, SiCO, SiCON, ZnO, HfO, HfZrO, ZrO, LaO, AlO, TiN, WN, TaN, MoN, HfN, and other suitable dielectric materials through a wave having a selected (or an optimized) frequency provided by the antenna system 310.

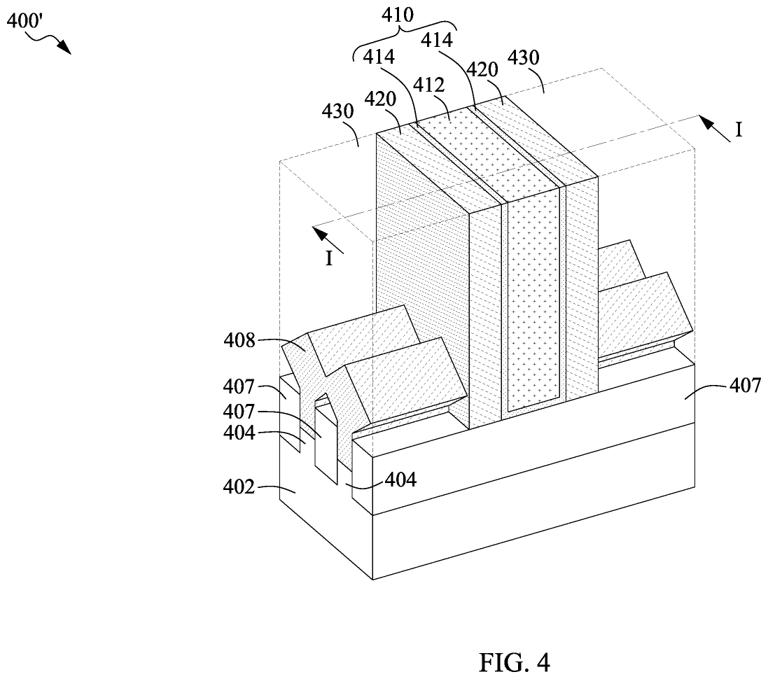

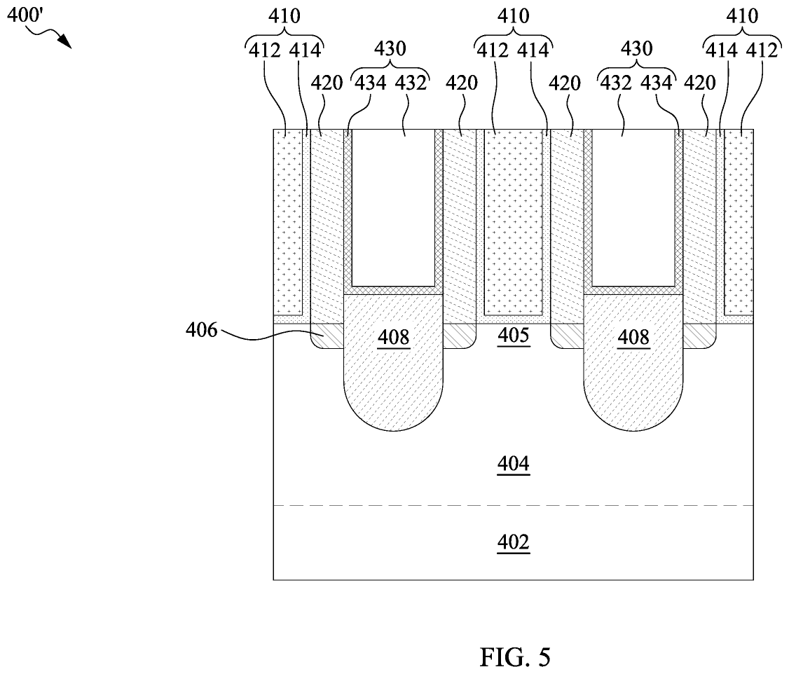

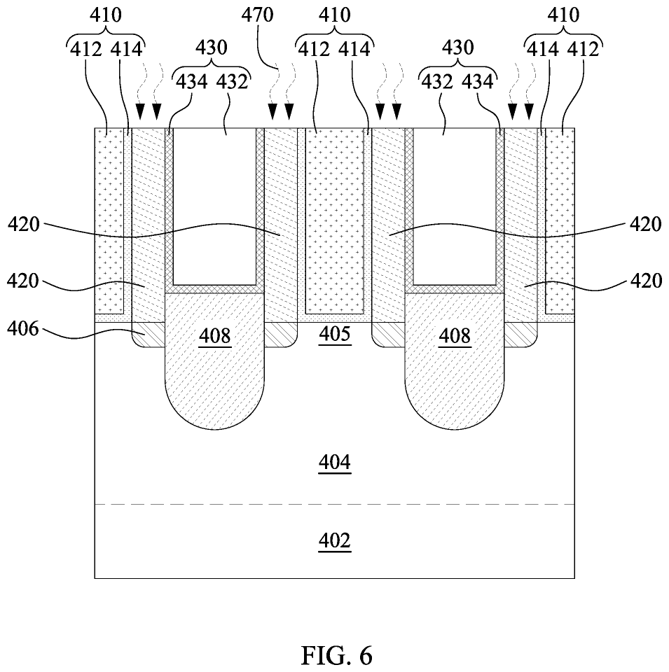

FIG. 4 is a schematic drawing illustrating a semiconductor structure 400 at a fabrication stage constructed according to aspects of the present disclosure in one or more embodiments. FIG. 4 further illustrates a reference cross-section I-I along a longitudinal axis of a fin structure. FIG. 5 is a cross-sectional view taken along the reference cross-section I-I of FIG. 4, except three gate structures are shown. FIGS. 6 to 13 are schematic drawings illustrating the semiconductor structure 400 at various fabrication stages constructed according to aspects of the present disclosure in one or more embodiments. FIGS. 6 to 13 are cross-sectional views illustrated along a cross-section similar to the reference cross-section I-I in FIG. 4, except three gate structures are shown.

Referring to FIGS. 4 and 5, a structure 400′ (e.g., the semiconductor structure 400 at the illustrated fabrication stage) is provided or received. The respective step is shown as the operation 102 of the method 100 in FIG. 1 or the operation 202 of the method 200 in FIG. 2. The structure 400′ may include a metal gate structure 410 and a dielectric structure 430 laterally surrounding the metal gate structure 410. In some embodiments, a sacrificial spacer 420 is interposed between the metal gate structure 410 and the dielectric structure 430. The semiconductor structure 400 may be a fin field-effect transistor (FinFET). The metal gate structure 410 may be disposed over one or more fins 404 extending from a substrate 402. The structure 400′ may further include shallow trench isolation (STI) regions 407 disposed over the substrate 402, wherein the fins 404 protrude from between neighboring STI regions 407. Although the fins 404 are illustrated as being a single, continuous material of the substrate 402, the fins 404 and/or the substrate 402 may include a single material or a plurality of materials. In alternative embodiments, the semiconductor structure 400 may be a planar metal oxide semiconductor field-effect transistor (MOSFET). For example, the metal gate structure 410 may be disposed over the substrate 402. In other embodiments, the semiconductor structure 400 may be a gate-all-around (GAA) transistor. For example, the metal gate structure 410 may be disposed over one or more nanowires or nanosheets extending from the substrate 402.

The substrate 402 may be a semiconductor substrate, such as a bulk semiconductor, a semiconductor-on-insulator (SOI) substrate, or the like, and may be doped (e.g., with a p-type or a n-type dopant) or undoped. The substrate 402 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate, may also be used. In some embodiments, the semiconductor material of the substrate 402 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The metal gate structure 410 may include a gate electrode 412 and a gate dielectric layer 414. The gate dielectric layer 414 may be disposed along sidewalls and over top surfaces of the fins 404, and the gate electrode 412 is disposed over the gate dielectric layer 414. In some embodiments, the gate dielectric layer 414 includes one or more layers of silicon oxide, silicon nitride, metal oxide, metal silicate, or the like. Although the gate dielectric layer 414 is shown as being single-layered in this embodiment, the gate dielectric layer 414 may include multiple sub-layers in some embodiments. For example, the gate dielectric layer 414 may include an interfacial layer (not shown) of silicon oxide formed by thermal or chemical oxidation and an overlying high-k dielectric material, such as a metal oxide or a silicate of hafnium, aluminum, zirconium, lanthanum, manganese, barium, titanium, lead, or combinations thereof. In some embodiments, the gate dielectric layer 414 may include a dielectric layer having a k-value greater than about 7.0. In some embodiments, the gate electrode 412 includes a plurality of sub-layers. For example, the gate electrode 412 may include a metal-containing material such as titanium nitride, titanium oxide, tantalum nitride, tantalum carbide, cobalt, ruthenium, aluminum, tungsten, combinations thereof, or multi-layers thereof.

Source/drain regions 408 are disposed on opposite sides of the fin 404 with respect to the metal gate structure 410. As used herein, the term “source/drain region(s)” may refer to a source or a drain, individually or collectively, depending upon the context. The source/drain regions 408 may be epitaxial source/drain regions. A material of the epitaxial source/drain regions 408 may be selected to exert stress in the respective channel regions 405, thereby improving performance. Lightly doped source/drain (LDD) regions 406 may be disposed adjacent to the source/drain regions 408.

The dielectric structure 430 is disposed over the source/drain regions 408 and the STI regions 407. The dielectric structure 430 may include an inter-layer dielectric (ILD) 432 and a contact etch stop layer (CESL) 434. In some embodiments, the ILD 432 includes phospho-silicate glass (PSG), boro-silicate glass (BSG), boron-doped phospho-silicate glass (BPSG), undoped silicate glass (USG), and/or other suitable dielectric materials. In some embodiments, the CESL 434 includes silicon nitride, silicon oxide, silicon oxynitride, and/or other suitable dielectric materials having an etch rate lower than that of the material of the ILD 432. In some embodiments, a width (or a thickness) of the CESL 434 is substantially in a range of from 2 nm to 10 nm.

The sacrificial spacer 420 separates the source/drain regions 408 from the metal gate structure 410. The sacrificial spacer 420 may further separate the metal gate structure 410 from the dielectric structure 430. The sacrificial spacer 420 may include insulating material, such as silicon carbide, silicon oxide, silicon nitride, a low-k material, or a combination thereof. The sacrificial spacer 420 may include a single layer or a stack of insulating layers. The sacrificial spacer 420 may have a low-k material with a dielectric constant less than about 3.9 (e.g., about 3.5, about 3.0, or about 2.8). In some embodiments, the sacrificial spacer 420 may include a material composed of silicon, oxygen, carbon, and/or nitrogen. The concentrations of silicon, oxygen, carbon, and nitrogen in the material of the sacrificial spacer 420 may depend on the desired dielectric constant of the sacrificial spacer 420. Varying concentrations of silicon, oxygen, carbon, and nitrogen in the material can vary the desired dielectric constant of the sacrificial spacer 420. In some embodiments, each sacrificial spacer 420 may include a layer of silicon oxycarbonitride (SiOCN), a layer of silicon carbon nitride (SiCN), a layer of silicon oxide carbide (SiOC), or a combination thereof. In some embodiments, each sacrificial spacer 420 may include a stack of a SiOCN layer disposed on a SiOC layer, which is disposed on a SiOCN layer. In some embodiments, a width (or a thickness) of the sacrificial spacer 420 is substantially in a range of from 2 nm to 10 nm. In some embodiments, the width (or the thickness) of the sacrificial spacer 420 is substantially equal to the width (or the thickness) of the CESL 434.

FIGS. 4 and 5 illustrate an exemplary semiconductor structure 400 with a low-k dielectric material (e.g., the sacrificial spacer 420). In some embodiments, the sacrificial spacer 420 may be damaged during or after formation of the metal gate structure 410. Additionally, the use of high-k dielectric materials in the gate dielectric layer 414 may not be entirely satisfactory in all respects. Accordingly, a replacement of the sacrificial spacer 420 (or the gate dielectric layer 414) may be desired. However, a removal of the sacrificial spacer 420 may be difficult since the sacrificial spacer 420 is laterally surrounded by the gate dielectric layer 414 and the CESL 434. The etch selectivity between the sacrificial spacer 420 and adjacent layers (e.g., the gate dielectric layer 414 and the CESL 434) may be low (e.g., less than 10:1) since the sacrificial spacer 420, the gate dielectric layer 414 and the CESL 434 are all composed of dielectric materials. Likewise, a removal of the gate dielectric layer 414 may be difficult since the gate dielectric layer 414 is adjacent to the sacrificial spacer 420, which is also formed of dielectric materials. As will be described in greater detail below, the in-situ selective heating assisted plasma etching operations provided by the processing system 300 may increase an etch selectivity between the target dielectric material (e.g., the sacrificial spacer 420) and adjacent dielectric materials (e.g., the gate dielectric layer 414 and the CESL 434).

The in-situ selective heating assisted plasma etching operations may include two sequential reaction cycles: (i) a material modification cycle, and (ii) a material removal cycle. The material modification cycle may selectively heat a target material or increase a temperature of a target material to modify an etch selectivity between the target material and adjacent materials. The modified material (i.e., the target material) may be subsequently removed during the next cycle (e.g., the material removal cycle). Any unmodified material (i.e., the adjacent materials), which is not heated during the material modification cycle, will have a significantly lower etch rate than the modified material and will not be removed. The material removal cycle may remove the modified material (or layer) while keeping the unmodified material(s) (or layers) intact. The modified material may have a temperature gradient in chemical composition and/or physical structure after the material modification cycle. For example, a temperature of the modified material may decrease along a depth direction from an upper surface to a bottom surface. The material removal cycle may remove the modified material having higher temperature while keeping the modified material having lower temperature intact. In other words, only a surface portion of the modified material is removed. Subsequently, a bottom portion of the modified material may be selectively heated in another material modification cycle. The bottom portion of the modified material may be removed in a subsequent material removal cycle. The total amount of the removed modified material may be controlled by a number of repeated cycles (e.g., the material modification cycle and the material removal cycle).

FIGS. 6 to 8 illustrate one or more material modification cycles and one or more material removal cycles of an exemplary in-situ selective heating assisted plasma etching operation to remove a portion of the sacrificial spacer 420, in accordance with some embodiments.

Referring to FIG. 6, in some embodiments, a temperature of the sacrificial spacer 420 is increased. In some embodiments, a treatment 470 is performed to selectively heat a bonding between a first atom and a second atom of the sacrificial spacer 420. The respective step is shown as the operation 104 of the method 100 in FIG. 1 or the operation 204 of the method 200 in FIG. 2. The sacrificial spacer 420 may include a material composed of a first atom, a second atom, a third atom and/or a fourth atom. As discussed previously, the first atom, the second atom, the third atom and the fourth atom may respectively comprise silicon (Si), carbon (C), nitrogen (N), and oxygen (O). In some embodiments, a concentration of the second atom in the sacrificial spacer 420 is substantially in a range of from 5% to 20%. The CESL 434 may include a material composed of the first atom, the third atom and/or the fourth atom. The gate dielectric layer 414 may include a material composed of the first atom, the fourth atom and/or a metal atom.

The bonding between the first atom and the second atom of the sacrificial spacer 420 may be selectively heated by a millimeter wave generated or provided by the antenna system 310. In some embodiments, a frequency of the millimeter wave is substantially in a range of from 30 GHz to 450 GHz. The frequency of the millimeter wave may be selected such that the bonding between the first atom and the second atom of the sacrificial spacer 420 may be selectively heated, while the bonding between first atom and the third atom (or the fourth atom) of the CESL 434 (or the gate dielectric layer 414) is not affected (not heated) by the frequency of the millimeter wave. In some embodiments, the selected frequency may depend on various factors, such as film thickness, grain size, dimension, composition ratio, porosity, dielectric constant, dielectric loss factor, and/or density of the target material. The bonding between the first atom and the second atom of the sacrificial spacer 420 may have greater thermal and/or kinetic energy after the selective heating operation. In some embodiments, the bonding between the first atom and the second atom of the sacrificial spacer 420 is configured as a heating source for heating the whole body of the sacrificial spacer 420. In some embodiments, the treatment 470 may be precisely controlled with pulsing-millimeter wave power, and/or millimeter-wave frequency modulation for phase, interference control, pulsing duty cycle and/or radiation time.

A temperature of the sacrificial spacer 420 is increased after the bonding between the first atom and the second atom of the sacrificial spacer 420 is selectively heated. In some embodiments, a temperature of the CESL 434 (or the gate dielectric layer 414) remains unchanged after the increase of the temperature of the sacrificial spacer 420. In some embodiments, a temperature difference between the sacrificial spacer 420 and the adjacent materials (e.g., the dielectric structure 430 or the metal gate structure 410) is substantially in a range of from 50° C. to 300° C. In other words, a temperature difference between the sacrificial spacer 420 and the adjacent CESL 434 (or the gate dielectric layer 414) is substantially in a range of from 50° C. to 300° C. In some embodiments, the temperature difference between the sacrificial spacer 420 and the adjacent CESL 434 (or the gate dielectric layer 414) is reached within a few milliseconds. In some embodiments, the temperature of the sacrificial spacer 420 is increased to about 400° C. within a few milliseconds. In some embodiments, a heating efficiency of the sacrificial spacer 420 is based on an amount of the bonding between the first atom and the second atom (e.g., a Si—C bonding) in chemical composition and/or physical structure. A greater temperature difference may be achieved if more bonding between the first atom and the second atom (e.g., a Si—C bonding) is present in the chemical composition and/or the physical structure of the sacrificial spacer 420.

In some embodiments, the sacrificial spacer 420 has an etch rate greater than those of the adjacent materials after the temperature of the sacrificial spacer 420 is increased. In some embodiments, an etch selectivity between the sacrificial spacer 420 and the adjacent materials (e.g., the dielectric structure 430 or the metal gate structure 410) is increased after the temperature of the sacrificial spacer 420 is increased. In other words, an etch selectivity between the sacrificial spacer 420 and the adjacent CESL 434 (or the gate dielectric layer 414) is increased. In some embodiments, prior to the treatment 470, the etch selectivity between the sacrificial spacer 420 and the adjacent layers (e.g., the gate dielectric layer 414 and the CESL 434) may be less than 10:1 (e.g., less than 2:1). In some embodiments, after the treatment 470, the etch selectivity between the sacrificial spacer 420 and the adjacent layers (e.g., the gate dielectric layer 414 and the CESL 434) may be greater than 10:1. For example, after the treatment 470, the etch selectivity between the sacrificial spacer 420 and the adjacent layers (e.g., the gate dielectric layer 414 and the CESL 434) may be greater than 30:1 or 50:1.

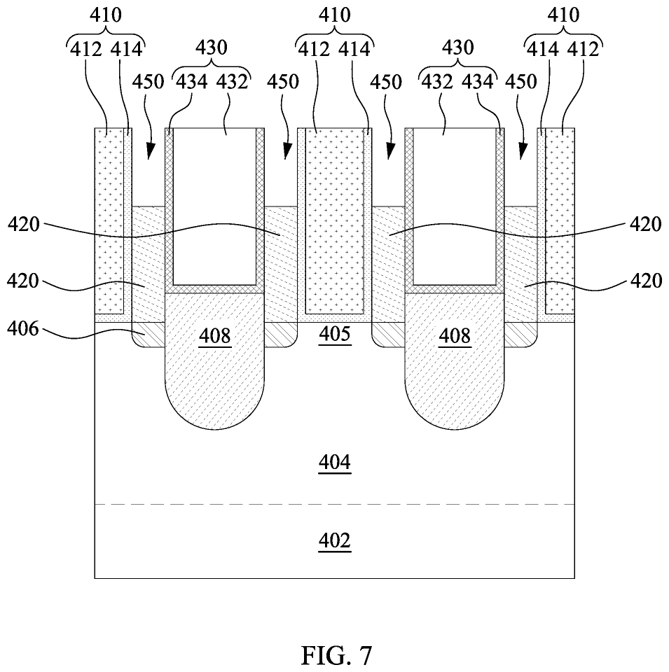

Referring to FIG. 7, in some embodiments, the sacrificial spacer 420 is selectively etched to reduce a thickness of the sacrificial spacer 420. The respective step is shown as the operation 206 of the method 200 in FIG. 2. In some embodiments, at least a portion of the sacrificial spacer 420 is removed to form a recess 450 between the metal gate structure 410 and the dielectric structure 430. The respective step is shown as the operation 106 of the method 100 in FIG. 1. In some embodiments, only a surface portion of the sacrificial spacer 420 is removed by a plasma etching operation, while a bottom portion of the sacrificial spacer 420 is kept intact. As discussed previously, the sacrificial spacer 420 may have a temperature gradient in chemical composition and/or physical structure after the material modification cycle. An etch selectivity between a surface portion of the sacrificial spacer 420 and the adjacent CESL 434 (or the gate dielectric layer 414) may be greater than an etch selectivity between a bottom portion of the sacrificial spacer 420 and the adjacent CESL 434 (or the gate dielectric layer 414). Thus, only the surface portion of the sacrificial spacer 420 is removed.

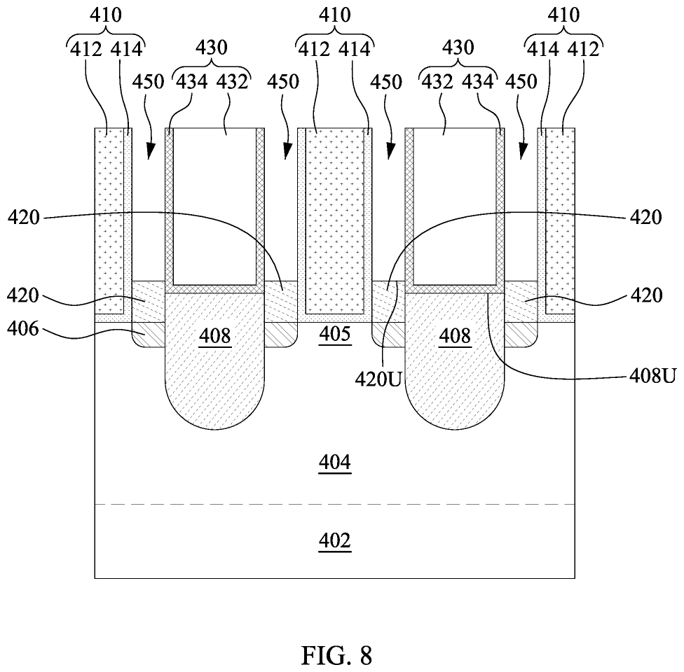

Referring to FIG. 8, in some embodiments, another portion of the sacrificial spacer 420 is removed. The recess 450 between the metal gate structure 410 and the dielectric structure 430 may be deepened. In some embodiments, the material modification cycle and the material removal cycle may be repeated to remove a portion of the remaining sacrificial spacer 420. In some embodiments, the steps of performing the treatment 470 and the selective etching may be repeated until at least a first portion of the sidewall of the gate dielectric layer 414 is exposed, wherein a portion of the sacrificial spacer 420 remains adjacent to a second portion of the sidewall of the gate dielectric layer 414. In some embodiments, an upper surface 420U of the remaining sacrificial spacer 420 is substantially higher than an upper surface 408U of the source/drain regions 408, so as to protect the source/drain regions 408.

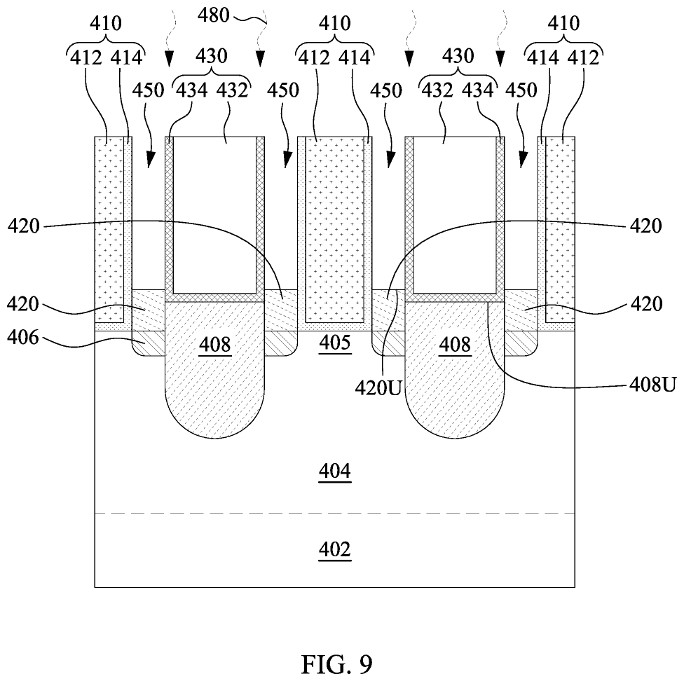

FIGS. 9 to 11 illustrate one or more material modification cycles and one or more material removal cycles of an exemplary in-situ selective heating assisted plasma etching operation to remove a portion of the CESL 434, in accordance with some embodiments.

Referring to FIG. 9, in some embodiments, a temperature of the CESL 434 is increased. In some embodiments, a treatment 480 is performed to selectively heat a bonding between the first atom and the third atom of the CESL 434. As discussed previously, the sacrificial spacer 420 may include a material composed of the first atom, the second atom, the third atom and/or the fourth atom. In some embodiments, a bonding between the first atom and the third atom of the sacrificial spacer 420 may also be heated. In some embodiments, a concentration of the third atom in the CESL 434 is greater than a concentration of the third atom in the sacrificial spacer 420. Accordingly, an increase in the temperature of the CESL 434 may be greater than an increase in the temperature of the sacrificial spacer 420. In some embodiments, the percentage of the third atom in the sacrificial spacer 420 is substantially in a range of from 3% to 40%.

The bonding between the first atom and the third atom of the CESL 434 may be selectively heated by a millimeter wave generated or provided by the antenna system 310. In some embodiments, a frequency of the millimeter wave is substantially in a range of from 1 GHz to 200 GHz. The frequency of the millimeter wave may be selected such that the bonding between the first atom and the third atom may be selectively heated, while the bonding between other atoms (e.g., the bonding between the first atom and the fourth atom) is not affected (not heated) by the frequency of the millimeter wave. In some embodiments, a temperature difference between the CESL 434 and the adjacent materials (e.g., the gate dielectric layer 414 or the sacrificial spacer 420) is substantially in a range of from 50° C. to 300° C.

In some embodiments, an etch selectivity between the CESL 434 and the adjacent gate dielectric layer 414 (or the sacrificial spacer 420) is increased. In some embodiments, prior to the treatment 480, the etch selectivity between the CESL 434 and the adjacent layers (e.g., the gate dielectric layer 414 and the sacrificial spacer 420) may be less than 10:1 (e.g., less than 2:1). In some embodiments, after the treatment 480, the etch selectivity between the CESL 434 and the adjacent layers (e.g., the gate dielectric layer 414 and the sacrificial spacer 420) may be greater than 10:1. For example, after the treatment 480, the etch selectivity between the CESL 434 and the adjacent layers (e.g., the gate dielectric layer 414 and the sacrificial spacer 420) may be greater than 30:1 or 50:1.

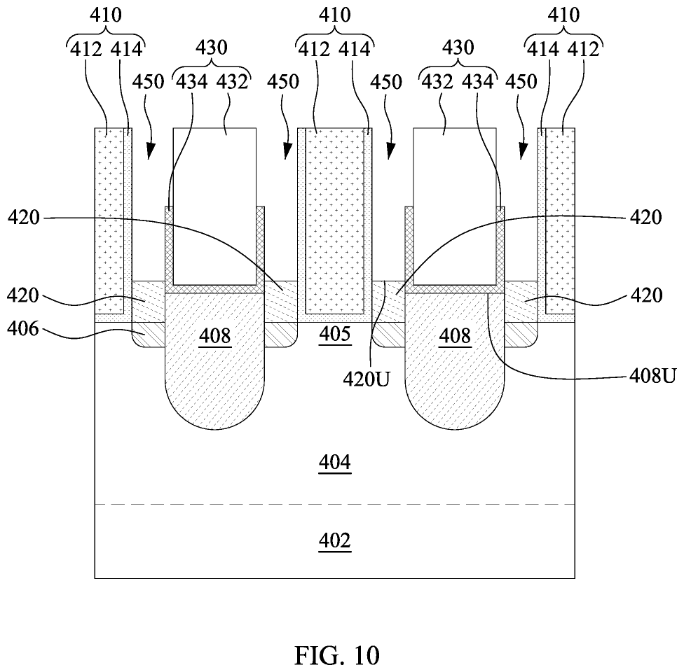

Referring to FIG. 10, in some embodiments, the CESL 434 is selectively etched to reduce a thickness of the CESL 434. In some embodiments, only a surface portion of the CESL 434 is removed by a plasma etching operation, while a bottom portion of the CESL 434 is kept intact. The CESL 434 may have a temperature gradient in chemical composition and/or physical structure after the material modification cycle. An etch selectivity between a surface portion of the CESL 434 and the adjacent gate dielectric layer 414 (or the sacrificial spacer 420) may be greater than an etch selectivity between a bottom portion of the CESL 434 and the adjacent gate dielectric layer 414 (or the sacrificial spacer 420). Thus, only the surface portion of the CESL 434 is removed.

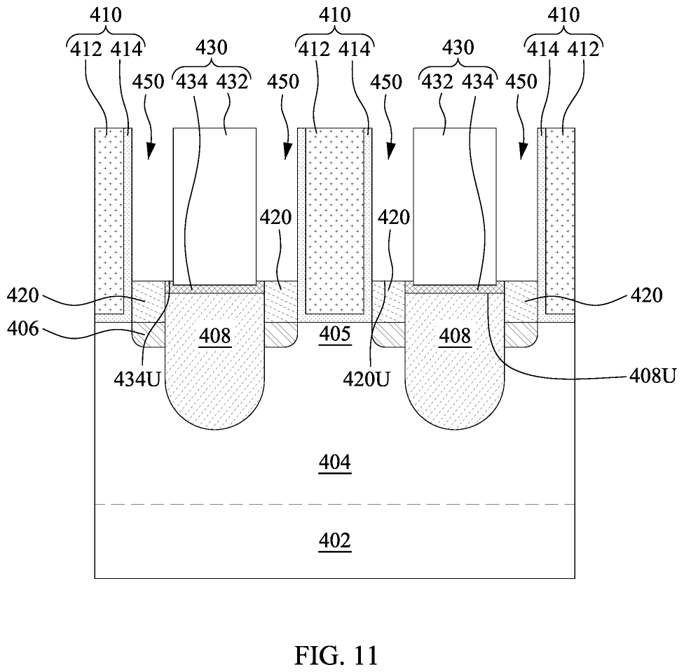

Referring to FIG. 11, in some embodiments, another portion of the CESL 434 is removed. In some embodiments, the material modification cycle and the material removal cycle may be repeated to remove the portion of the remaining CESL 434. In some embodiments, an upper surface 434U of the remaining CESL 434 is substantially higher than the upper surface 408U of the source/drain regions 408, so as to protect the source/drain regions 408. In some embodiments, the upper surface 434U of the CESL 434 is substantially level with the upper surface 420U of the sacrificial spacer 420.

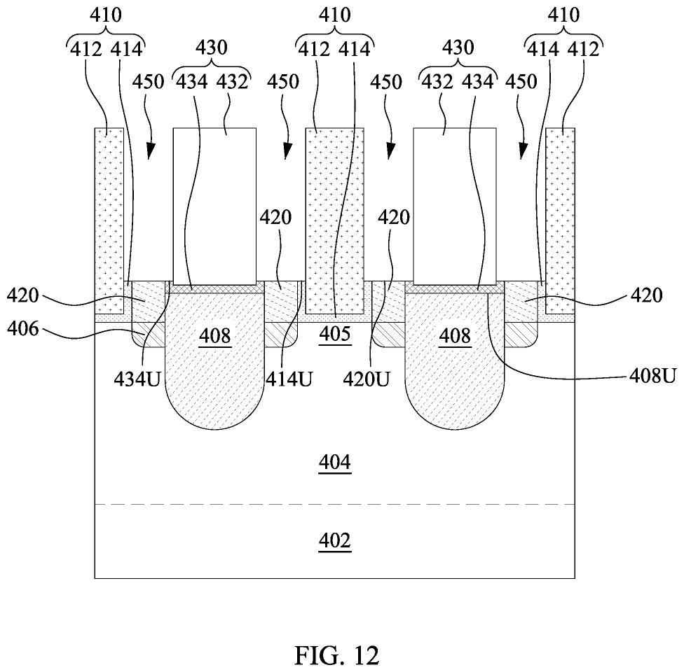

Referring to FIG. 12, in some embodiments, a surface portion of the gate dielectric layer 414 is removed. The respective step is shown as the operation 208 of the method 200 in FIG. 2. In some embodiments, the material modification cycle and the material removal cycle may be repeated to remove the surface portion of the gate dielectric layer 414. For example, a treatment may be performed to selectively heat a bonding between the first atom and the fourth atom of the gate dielectric layer 414. Alternatively, a bonding between the metal atom and the fourth atom of the gate dielectric layer 414 may be selectively heated. In some embodiments, an upper surface 414U of the remaining gate dielectric layer 414 is substantially level with the upper surface 420U of the sacrificial spacer 420.

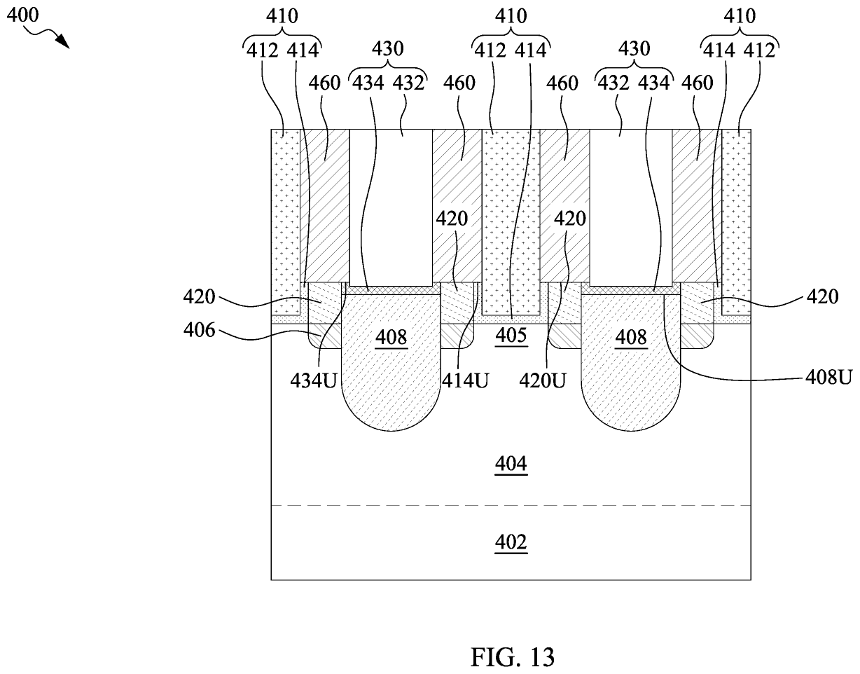

Referring to FIG. 13, in some embodiments, a spacer 460 is formed along a sidewall of the metal gate structure 410. The respective step is shown as the operation 108 of the method 100 in FIG. 1. The spacer 460 may be formed along a sidewall of the gate electrode 412 and a sidewall of the ILD 432. The spacer 460 is formed over the remaining portion of the sacrificial spacer 420, the remaining portion of the CESL 434 and the remaining portion of the gate dielectric layer 414. The spacer 460 may be interposed between the sidewall of the gate electrode 412 and the sidewall of the ILD 432. The spacer 460 may directly contact the sidewall of the gate electrode 412 and the sidewall of the ILD 432. The spacer 460 is disposed over the upper surface 420U of the sacrificial spacer 420, the upper surface 434U of the CESL 434 and the upper surface 414U of the gate dielectric layer 414. The spacer 460 and the sacrificial spacer 420 may together be configured as a spacer structure of the semiconductor structure 400.

The spacer 460 may include insulating material, such as silicon oxide, silicon nitride, a low-k material, or a combination thereof. The spacer 460 may have a low-k material with a dielectric constant less than about 3.9 (e.g., about 3.5, about 3.0, or about 2.8). In some embodiments, the spacer 460 may include a material composed of silicon, oxygen, carbon and/or nitrogen. The concentrations of silicon, oxygen, carbon and nitrogen in the material of the spacer 460 may depend on the desired dielectric constant of the spacer 460. In some embodiments, the concentrations of silicon, oxygen, carbon and nitrogen in the material of the spacer 460 is substantially same as those of the sacrificial spacer 420.

The structures and methods of the present disclosure are not limited to the above-mentioned embodiments, and may have other different embodiments. To simplify the description and for the convenience of comparison between each of the embodiments of the present disclosure, identical (or like) numerical labels in different drawings indicate substantially identical (or like) components or equivalents thereof. For making it easier to compare the difference between the embodiments, the following description will detail the dissimilarities among different embodiments and the identical features will not be redundantly described.

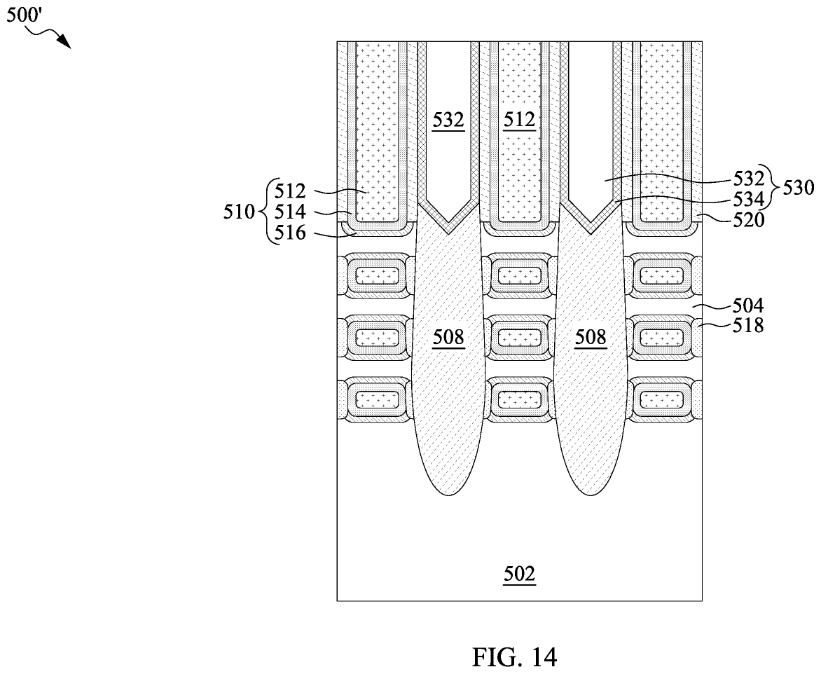

FIGS. 14 to 18 are schematic drawings illustrating a semiconductor structure 500 at various fabrication stages constructed according to aspects of the present disclosure in one or more embodiments.

Referring to FIG. 14, a structure 500′ (e.g., the semiconductor structure 500 at the illustrated fabrication stage) is provided or received. The structure 500′ may include a sacrificial spacer 520 interposed between a metal gate structure 510 and a dielectric structure 530. The metal gate structure 510 may be disposed over one or more nanowires (or nanosheets) 504 extending from the substrate 502. The metal gate structure 510 may include a gate electrode 512 and a gate dielectric layer 514. The metal gate structure 510 may further include an interfacial layer 516 of silicon oxide formed by thermal or chemical oxidation. The gate dielectric layer 514 may include a high-k dielectric material similar to those of the gate dielectric layer 414. Source/drain structures 508 are disposed on opposite sides of the nanowires 504 with respect to the metal gate structure 510. As used herein, the term “source/drain structure(s)” may refer to a source or a drain, individually or collectively, depending upon the context. The dielectric structure 530 is disposed over the source/drain structures 508. The dielectric structure 530 may include an inter-layer dielectric (ILD) 532 and a contact etch stop layer (CESL) 534. In some embodiments, the ILD 532 and the CESL 534 may respectively be formed of materials similar to those of the ILD 432 and the CESL 434. In some embodiments, a width (or a thickness) of the CESL 534 is substantially in a range of from 2 nm to 10 nm.

Inner spacer structures 518 may be formed between the source/drain structures 508 and portions of the metal gate structure 510, which are between adjacent nanowires 504, according to some embodiments. The inner spacer structures 518 may include insulating material, such as silicon carbide, silicon oxide, silicon nitride, a low-k material, or a combination thereof. The inner spacer structures 518 may include a single layer or a stack of insulating layers. The inner spacer structures 518 may have a low-k material with a dielectric constant less than about 3.9 (e.g., about 3.5, about 3.0, or about 2.8). In some embodiments, the inner spacer structures 518 may include a material composed of silicon, oxygen, carbon and/or nitrogen. The concentrations of silicon, oxygen, carbon and nitrogen in the material of the inner spacer structure 518 may depend on the desired dielectric constant of the inner spacer structure 518.

The sacrificial spacer 520 separates the source/drain regions 508 or the dielectric structure 530 from the metal gate structure 510. The sacrificial spacer 520 may be formed of materials similar to those of the sacrificial spacer 420. The concentrations of silicon, carbon, nitrogen and oxygen in the material of the sacrificial spacer 520 may be different from the concentrations of silicon, carbon, nitrogen and oxygen in the material of the inner spacer structure 518. In some embodiments, a concentration of the carbon of the sacrificial spacer 520 is greater than that of the inner spacer structure 518. In some embodiments, the sacrificial spacer 520 includes SiOCN or SiCN, while the inner spacer structure 518 includes SiOCN, SiOC or SiCN. In some embodiments, a width (or a thickness) of the sacrificial spacer 520 is substantially in a range of from 2 nm to 10 nm. In some embodiments, the width (or the thickness) of the sacrificial spacer 520 is substantially equal to the width (or the thickness) of the CESL 534.

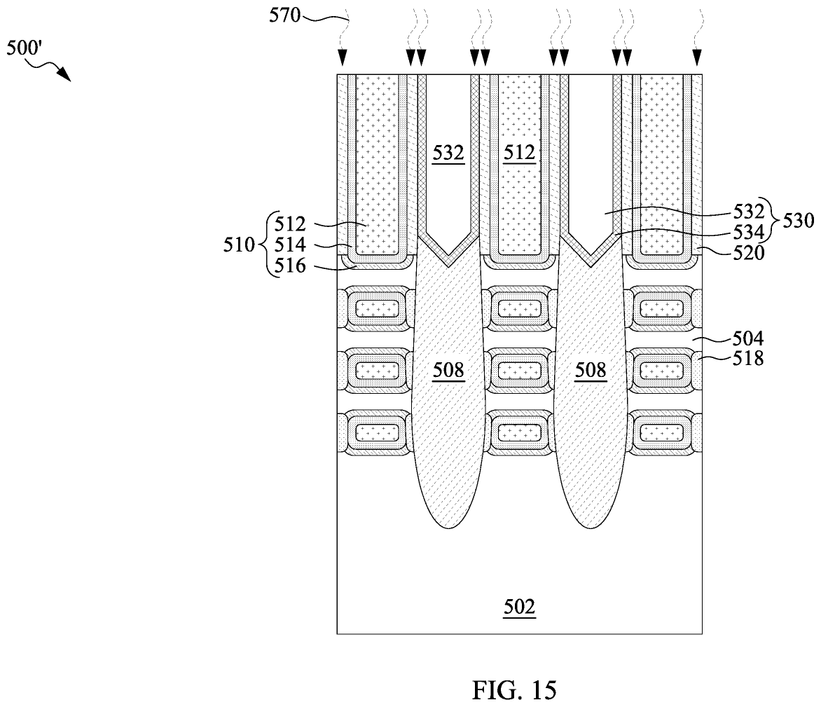

FIG. 15 illustrates one or more material modification cycles and one or more material removal cycles of an exemplary in-situ selective heating assisted plasma etching operation to remove a portion of the sacrificial spacer 520 and a portion of the CESL 534, in accordance with some embodiments. The sacrificial spacer 520 and the inner spacer structure 518 may respectively include a material composed of a first atom, a second atom, a third atom and/or a fourth atom. The CESL 534 may include a material composed of the first atom, the third atom and/or the fourth atom. The gate dielectric layer 514 may include a material composed of the first atom, the fourth atom and/or a metal atom. The first atom, the second atom, the third atom and the fourth atom may respectively comprise silicon, carbon, nitrogen and oxygen.

Referring to FIG. 15, a treatment 570 is performed to selectively heat a first bonding between the first atom and the second atom and a second bonding between the first atom and the third atom. The sacrificial spacer 520 includes the first atom, the second atom, and the third atom. The CESL 534 includes the first atom and the third atom. Thus, both the sacrificial spacer 520 and the CESL 534 may be heated during the treatment 570. In some embodiments, the inner spacer structure 518 may also be heated. In some embodiments, a concentration of the second atom in the sacrificial spacer 520 is greater than a concentration of the second atom in the inner spacer structure 518. Accordingly, an increase of the temperature of the sacrificial spacer 420 may be greater than that of the inner spacer structure 518.

The first bonding and the second bonding may be selectively heated by a millimeter wave generated or provided by the antenna system 310. In some embodiments, a frequency of the millimeter wave is substantially in a range of from 50 GHz to 150 GHz. The frequency of the millimeter wave may be selected such that the first bonding and the second bonding may be concurrently heated, while other bondings (e.g., a third bonding between the first atom and the fourth atom) in the gate dielectric layer 514 (or the inner spacer structure 518) are not affected (not heated) by the frequency of the millimeter wave.

A temperature of the sacrificial spacer 520 and a temperature of the CESL 534 are increased after the first bonding and the second bonding are selectively heated. In some embodiments, a temperature of the gate dielectric layer 514 remains unchanged, while the temperature of the sacrificial spacer 520 and the temperature of the CESL 534 are increased. In some embodiments, temperature differences between the sacrificial spacer 520, the CESL 534 and the adjacent materials (e.g., the ILD 532 or the gate dielectric layer 514) are substantially in a range of from 50° C. to 300° C.

In some embodiments, an etch selectivity between the sacrificial spacer 520, the CESL 534 and the adjacent materials (e.g., the ILD 532 or the gate dielectric layer 514) is increased after the temperature of the sacrificial spacer 520 and the temperature of the CESL 534 are increased. In some embodiments, prior to the treatment 570, the etch selectivity between the sacrificial spacer 520, the CESL 534 and the adjacent materials (e.g., the ILD 532 or the gate dielectric layer 514) may be less than 10:1 (e.g., less than 2:1). In some embodiments, after the treatment 570, the etch selectivity between the sacrificial spacer 520, the CESL 534 and the adjacent materials (e.g., the ILD 532 or the gate dielectric layer 514) may be greater than 10:1. For example, after the treatment 570, the etch selectivity may be greater than 30:1 or 50:1.

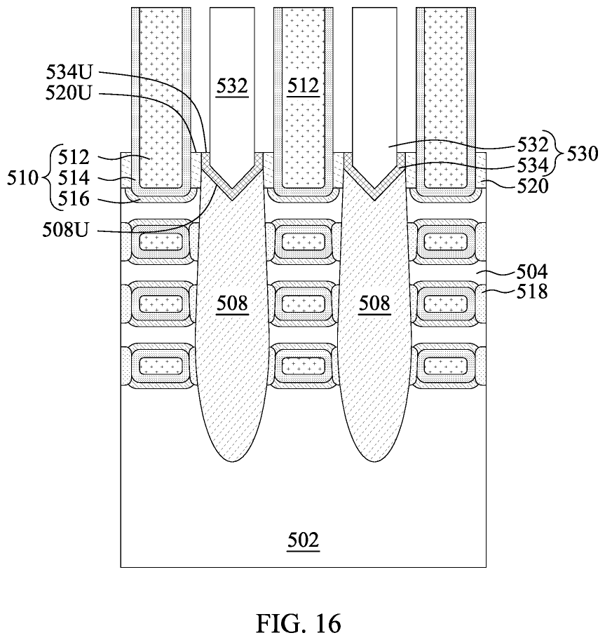

Referring to FIG. 16, in some embodiments, the sacrificial spacer 520 and the CESL 534 are selectively etched. In some embodiments, the material modification cycle and the material removal cycle may be repeated to remove a surface portion of the sacrificial spacer 520 and a surface portion of the CESL 534. In some embodiments, the steps of performing the treatment 570 and the selective etching may be repeated until at least a first portion of the sidewall of the gate dielectric layer 514 is exposed, and a remaining portion of the sacrificial spacer 520 remains adjacent to a second portion of the sidewall of the gate dielectric layer 514. In some embodiments, an upper surface 520U of the remaining sacrificial spacer 520 is higher than an upper surface 508U of the source/drain structures 508, so as to protect the source/drain structures 508. In some embodiments, an upper surface 534U of the remaining CESL 534 is higher than the upper surface 508U of the source/drain structures 508, so as to protect the source/drain structures 508. In some embodiments, the upper surface 520U of the remaining sacrificial spacer 520 is substantially level with the upper surface 534U of the remaining CESL 534.

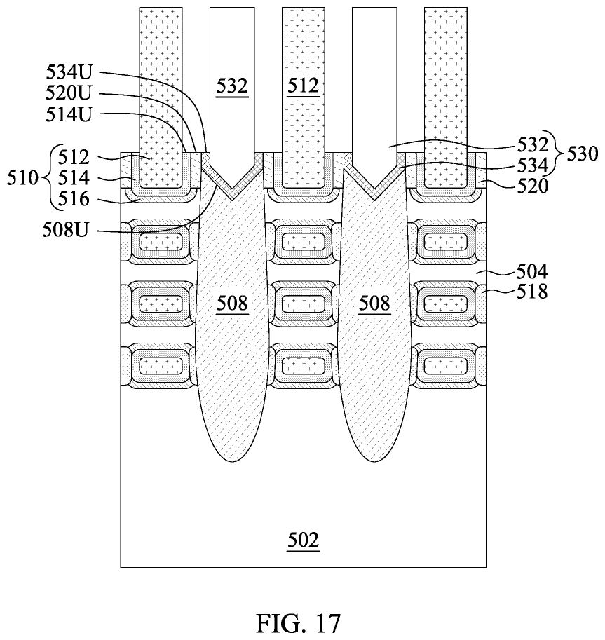

Referring to FIG. 17, in some embodiments, a surface portion of the gate dielectric layer 514 is removed. In some embodiments, the material modification cycle and the material removal cycle may be repeated to remove the surface portion of the gate dielectric layer 514. In some embodiments, an upper surface 514U of the remaining gate dielectric layer 514 is substantially level with the upper surface 520U of the sacrificial spacer 520.

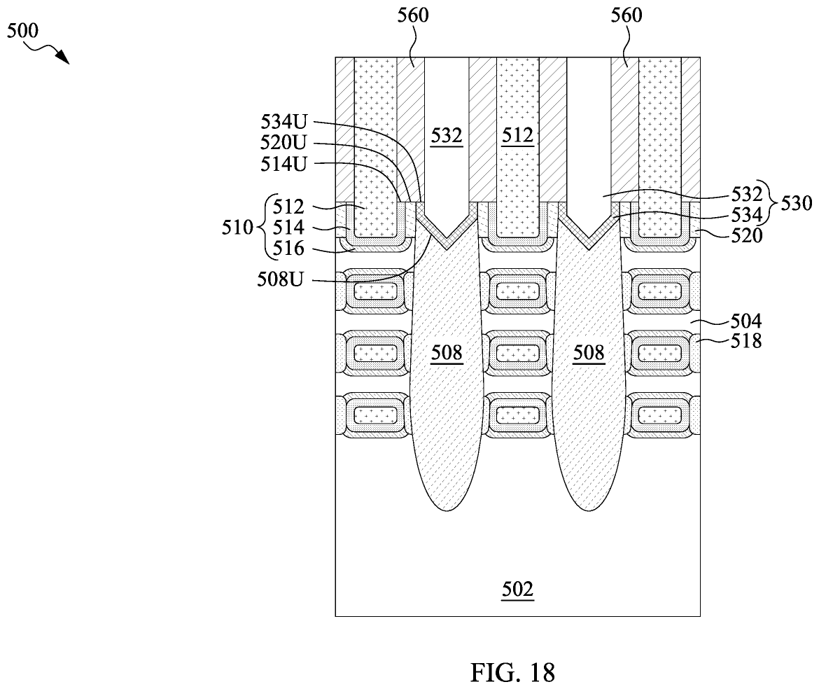

Referring to FIG. 18, in some embodiments, a spacer 560 is formed along a sidewall of the gate electrode 512 and a sidewall of the ILD 532. The spacer 560 may directly contact the sidewall of the gate electrode 512 and the sidewall of the ILD 532. The spacer 560 is formed over the remaining portion of the sacrificial spacer 520, the remaining portion of the CESL 534 and the remaining portion of the gate dielectric layer 514. The spacer 560 is disposed over the upper surface 520U of the sacrificial spacer 520, the upper surface 534U of the CESL 534 and the upper surface 514U of the gate dielectric layer 514. The spacer 560 and the sacrificial spacer 520 may together be configured as a spacer structure of the semiconductor structure 500. The spacer 560 may be formed of materials similar to those of the spacer 460.

The present disclosure provides embodiments of methods for forming a semiconductor structure that provide one or more improvements over existing approaches. By using an in-situ selective heating assisted plasma etching operation as described above, an etch selectivity between a target dielectric material and adjacent dielectric materials may be increased. Accordingly, a removal of a sacrificial spacer layer may be achieved without substantially etching and/or damaging nearby dielectric materials. Following the removal of the sacrificial spacer layer, a removal of a gate dielectric layer may be achieved without substantially etching and/or damaging nearby structures (e.g., a gate electrode). Furthermore, with the removal of or a replacement of the gate dielectric layer, the resulting transistor device may have a reduced parasitic capacitance or a greater speed. Additionally, since the selective heating operation may be performed in-situ in a same chamber as the plasma etching operation, the proposed method may provide benefits by lowering associated costs and/or increasing production efficiency.

The in-situ selective heating assisted plasma etching operation may also be used to increase an etch rate selectivity between inner spacer structures and adjacent materials. For another example, in a GAA process flow, formation of inner spacers can be an important process to reduce capacitance and prevent leakage between gate stacks and source/drain (S/D) regions. However, dimensions of inner spacers may be difficult to control during an etching process. Further, nanowires as channel regions may also suffer damage, such as oxidation or loss due to excess etching during the formation of inner spacers, which degrades device performance. An etch rate selectivity between inner spacer structures and adjacent materials may be increased by selectively heating the inner spacer structures. Accordingly, the dimensions of the inner spacers may be easier to control without substantially etching and/or damaging nearby nanowires.

In accordance with some embodiments of the present disclosure, a method for forming a semiconductor structure is provided. The method includes the following operations. A structure is received. The structure includes a metal gate structure and a dielectric structure laterally surrounding the metal gate structure, wherein a sacrificial spacer is interposed between the metal gate structure and the dielectric structure. A temperature of the sacrificial spacer is increased. At least a portion of the sacrificial spacer is removed to form a recess between the metal gate structure and the dielectric structure. A spacer is formed in the recess along a sidewall of the metal gate structure.

In accordance with some embodiments of the present disclosure, a method for forming a semiconductor structure is provided. The method includes the following operations. A structure is received. The structure includes a gate structure and a sacrificial spacer along a sidewall of the gate structure, wherein the gate structure comprises a gate electrode and a gate dielectric layer, and the sacrificial spacer is adjacent to the gate dielectric layer. A treatment is preformed to selectively heat a bonding between a first atom and a second atom of the sacrificial spacer. The sacrificial spacer is selectively etched to reduce a thickness of the sacrificial spacer. A surface portion of the gate dielectric layer is removed.

In accordance with some embodiments of the present disclosure, a semiconductor structure is provided. The semiconductor structure includes a plurality of nanowires, a gate structure, source/drain structures and spacer structures. The gate structure is disposed over the plurality of nanowires, and the gate structure comprises a gate electrode and a gate dielectric layer. The source/drain structures are disposed at two ends of each of the plurality of nanowires. The spacer structures are disposed at two opposite sides of the gate structure. Each of the spacer structures comprises a first spacer adjacent to a sidewall of the gate dielectric layer and a second spacer adjacent to a sidewall of the gate electrode, wherein the second spacer is disposed over the first spacer and a top surface of the gate dielectric layer.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
receiving a structure comprising a metal gate structure and a dielectric structure laterally surrounding the metal gate structure, wherein a sacrificial spacer is interposed between the metal gate structure and the dielectric structure;
increasing a temperature of the sacrificial spacer;
removing at least a portion of the sacrificial spacer to form a recess between the metal gate structure and the dielectric structure; and
forming a spacer in the recess along a sidewall of the metal gate structure.

2. The method of claim 1, wherein the sacrificial spacer comprises a first atom and a second atom different from the first atom, and the temperature of the sacrificial spacer is increased by heating a bonding between the first atom and the second atom.

3. The method of claim 2, wherein the dielectric structure comprises a contact etch stop layer adjacent to the sacrificial spacer, and a temperature of the contact etch stop layer remains unchanged after the increase of the temperature of the sacrificial spacer.

4. The method of claim 3, wherein the contact etch stop layer comprises the first atom and a third atom different from the second atom and the first atom.

5. The method of claim 4, wherein the first atom comprises silicon (Si), the second atom comprises carbon (C), and the third atom comprises nitrogen (N).

6. The method of claim 5, wherein a concentration of the second atom in the sacrificial spacer is substantially in a range of from 5% to 20%.

7. The method of claim 1, wherein the temperature of the sacrificial spacer is increased by a millimeter wave generated by a millimeter-wave beamforming antenna system.

8. The method of claim 7, wherein a frequency of the millimeter wave is substantially in a range of from 30 GHz to 450 GHz.

9. The method of claim 1, wherein a temperature difference between the sacrificial spacer and the dielectric structure is substantially in a range of from 50° C. to 300° C.

10. The method of claim 1, wherein an etch selectivity between the sacrificial spacer and the dielectric structure is increased after the temperature of the sacrificial spacer is increased.

11. A method for forming a semiconductor structure, comprising:
receiving a structure comprising a gate structure and a sacrificial spacer along a sidewall of the gate structure, wherein the gate structure comprises a gate electrode and a gate dielectric layer, and the sacrificial spacer is adjacent to the gate dielectric layer;
performing a treatment to selectively heat a bonding between a first atom and a second atom of the sacrificial spacer;
selectively etching the sacrificial spacer to reduce a thickness of the sacrificial spacer; and
removing a surface portion of the gate dielectric layer.

12. The method of claim 11, further comprising:
forming a spacer along a sidewall of the gate electrode.

13. The method of claim 12, further comprising:
repeating the steps of performing the treatment and selectively etching until at least a first portion of a sidewall of the gate dielectric layer is exposed, wherein a portion of the sacrificial spacer remains adjacent to a second portion of the sidewall of the gate dielectric layer.

14. The method of claim 13, wherein the spacer is formed over the portion of the sacrificial spacer.

15. The method of claim 11, wherein the structure further comprises a dielectric structure adjacent to the sacrificial spacer, and the sacrificial spacer is between the gate dielectric layer and the dielectric structure.

16. The method of claim 15, further comprising:
removing a surface portion of the dielectric structure prior to removing the surface portion of the gate dielectric layer.

17. The method of claim 11, wherein the sacrificial spacer comprises a low-k dielectric material, and the gate dielectric layer comprises a high-k dielectric material.

18. The method of claim 17, wherein the low-k dielectric material comprises SiCON or SiCN.

19. A semiconductor structure, comprising:
a plurality of nanowires;
a gate structure disposed over the plurality of nanowires, the gate structure comprising a gate electrode and a gate dielectric layer;
source/drain structures disposed at two ends of each of the plurality of nanowires; and
spacer structures disposed at two opposite sides of the gate structure, wherein each of the spacer structures comprises a first spacer adjacent to a sidewall of the gate dielectric layer and a second spacer adjacent to a sidewall of the gate electrode, wherein the second spacer is disposed over the first spacer and a top surface of the gate dielectric layer.

20. The semiconductor structure of claim 19, wherein the second spacer directly contacts the sidewall of the gate electrode.
